(19) United States
(12) Patent Application Publication
(10) Pub. No.: US 2014/0085979 A1
(43) Pub. Date: Mar. 27, 2014

(54) NONVOLATILE SEMICONDUCTOR MEMORY DEVICE

(71) Applicant: KABUSHIKI KAISHA TOSHIBA, Tokyo (JP)

(72) Inventor: Fumihiro KONO, Kanagawa (JP)

(73) Assignee: Kabushiki Kaisha Toshiba, Tokyo (JP)

(21) Appl. No.: 13/803,458

(22) Filed: Mar. 14, 2013

(30) Foreign Application Priority Data
Sep. 27, 2012 (JP) 2012-213604

(51) Int. Cl. G11C 16/06

(52) U.S. Cl. CPC G11C 16/06
USPC 365/185.11; 365/185.17

(57) ABSTRACT

A memory cell array according to an embodiment includes a plurality of NAND strings with a plurality of memory cells stacked, and a bit line is connected to the NAND string. A word line is connected to a gate of the memory cell. A column system circuit is disposed directly under the memory cell array. When viewed from the top side, a global signal supply unit is disposed outside the memory cell array to supply a global signal to the column system circuit. When viewed from the top side, an upper interconnection is disposed over the bit line outside the memory cell array to transmit the global signal. A lower interconnection is disposed under the memory cell array to transmit the global signal to the column system circuit. A contact plug is configured to connect the upper interconnection and the lower interconnection.

### CROSS-REFERENCE TO RELATED APPLICATIONS

This application is based upon and claims the benefit of priority from Japanese Patent Application No. 2012-213604, filed on Sep. 27, 2012; the entire contents of which are incorporated herein by reference.

### FIELD

Embodiments described herein relate generally to nonvolatile semiconductor memory devices.

### BACKGROUND

In order to provide high-density integration of a NAND flash memory, a stacked NAND flash memory including memory cells arranged three-dimensionally is being proposed. In the stacked NAND flash memory, in order to reduce a layout area, peripheral circuits such as a sense amplifier circuit and a data latch circuit are disposed directly under stacked memory cells.

### BRIEF DESCRIPTION OF THE DRAWINGS

FIG. 1 is a perspective view illustrating a schematic configuration of a nonvolatile semiconductor memory device according to a first embodiment;

FIG. 2 is a perspective view illustrating a comparative example of the nonvolatile semiconductor memory device of FIG. 1;

FIG. 3 is a circuit diagram illustrating a schematic block configuration of the nonvolatile semiconductor memory device of FIG. 1;

FIG. 4 is a perspective view illustrating a schematic configuration of the memory cell array of the nonvolatile semiconductor memory device of FIG. 1;

FIG. 5 is an enlarged cross-sectional view of the NAND string NS of FIG. 4;

FIG. 6A is a cross-sectional view illustrating a schematic configuration of the peripheral circuit region of the nonvolatile semiconductor memory device of FIG. 1, FIG. 6B is a cross-sectional view illustrating a schematic configuration of the word line extension portion of the nonvolatile semiconductor memory device of FIG. 1, FIG. 6C is a cross-sectional view illustrating a schematic configuration of the memory cell array of FIG. 1 cut in a word line direction, and FIG. 6D is a cross-sectional view illustrating a schematic configuration of the memory cell array of FIG. 1 cut in a bit line direction;

FIG. 7 is a plan view illustrating a schematic configuration of a nonvolatile semiconductor memory device according to a second embodiment;

FIG. 8 is a cross-sectional view illustrating a schematic configuration of the memory cell array of FIG. 7 cut in a bit line direction;

FIG. 9 is a perspective view illustrating a schematic configuration of a nonvolatile semiconductor memory device according to a third embodiment; and

FIG. 10 is a block diagram illustrating a schematic configuration of a nonvolatile semiconductor memory device according to a fourth embodiment.

### DETAILED DESCRIPTION

A nonvolatile semiconductor memory device according to an embodiment is provided with a memory cell array, a bit line, a word line, a column system circuit, a global signal supply unit, an upper interconnection, a lower interconnection, and a contact plug. The memory cell array includes a plurality of NAND strings with a plurality of memory cells stacked. The bit line is connected to the NAND string. The word line is connected to a gate of the memory cell. The column system circuit is disposed directly under the memory cell array. When viewed from the top side, the global signal supply unit is disposed outside the memory cell array to supply a global signal to the column system circuit. When viewed from the top side, the upper interconnection is disposed over the bit line outside the memory cell array to transmit the global signal. The lower interconnection is disposed under the memory cell array to transmit the global signal to the column system circuit. The contact plug is configured to connect the upper interconnection and the lower interconnection.

Hereinafter, nonvolatile semiconductor memory devices according to embodiments will be described with reference to the drawings. Also, the present invention is not limited by these embodiments.

### First Embodiment

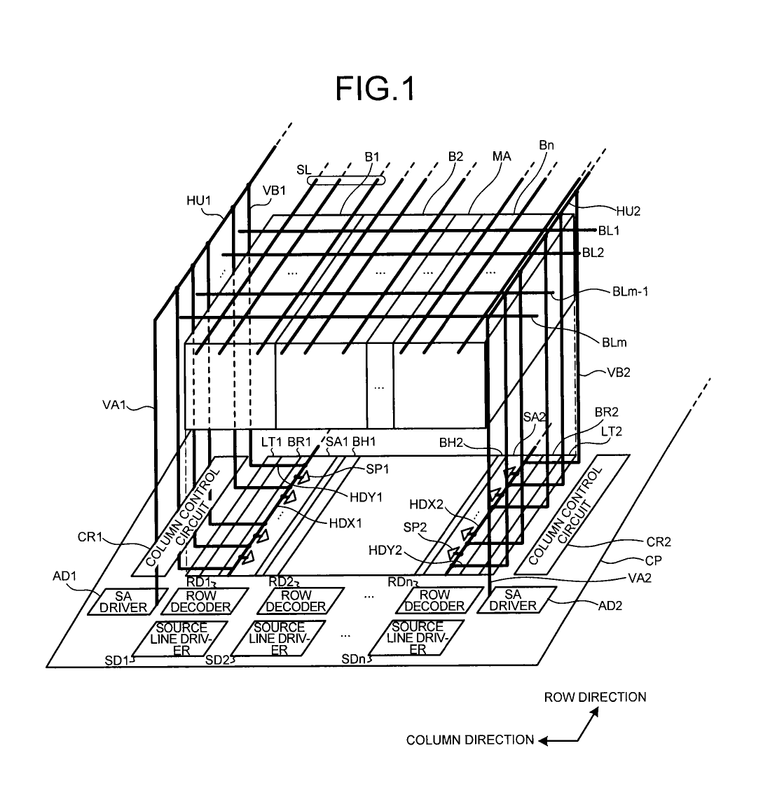

FIG. 1 is a perspective view illustrating a schematic configuration of a nonvolatile semiconductor memory device according to a first embodiment.

Referring to FIG. 1, a memory cell array MA is formed over a semiconductor substrate CP. The memory cell array MA includes a plurality of blocks B1 to Bn (n is a positive integer) including a plurality of memory cells that are three-dimensionally disposed. Herein, a cell transistor included in the memory cell is connected in series in a normal direction (height direction) with respect to the semiconductor substrate CP to constitute a NAND string.

On the memory cell array MA, a source line SL is disposed to extend in a row direction. The source line SL has a function of supplying a source potential to the NAND string. Bit lines BL1 to BLm (m is a positive integer) are provided on the source line SL. Herein, a plurality of bit lines BL1 to BLm are disposed to extend in a column direction perpendicular to the row direction. For the convenience of description, the bit lines BL1 to BLm will be generally referred to simply as a bit line BL.

In the semiconductor substrate CP, as a column system circuit, column control circuits CR1 and CR2, sense amplifier units SA1 and SA2, logic circuits BR1 and BR2, data latch units LT1 and LT2, and bit line hookup units BH1 and BH2 are formed. In addition, in the semiconductor substrate CP, as a global signal supply unit, SA drivers AD1 and AD2 are formed. Herein, the sense amplifier units SA1 and SA2 are provided with sense amplifier circuits SP1 and SP2. Each of the sense amplifier circuits SP1 and SP2 is connected to any corresponding one of the bit lines BL1 to BLm. The connection need not to be a structural connection if the connection is an electrically connection. Also, on the semiconductor substrate CP, as a row system circuit, row decoders RD1 to RDn and source line drivers SD1 to SDn are formed in respective blocks B1 to Bn.

Herein, the column control circuit CR1, the SA driver AD1, the sense amplifier unit SA1, the logic circuit BR1, the data latch unit LT1, and the bit line hookup unit BH1 are connected to the odd-numbered bit lines BL. The column control circuit CR2, the SA driver AD2, the sense amplifier unit SA2, the logic circuit BR2, the data latch unit LT2, and the bit line hookup unit BH2 are connected to the even-numbered bit lines BL.

Herein, the sense amplifier units SA1 and SA2, the logic circuits BR1 and BR2, the data latch units LT1 and LT2, and the bit line hookup units BH1 and BH2 are disposed directly under the memory cell array MA.

Also, the column control circuits CR1 and CR2 can perform column system control, and can include a column decoder. The SA drivers AD1 and AD2 can respectively drive the sense amplifier units SA1 and SA2. When reading data from the memory cells, the sense amplifier units SA1 and SA2 read the data by, for example, detecting the potentials of the bit lines BL1 to BLm or detecting the cell currents flowing through the memory cells. Also, the sense amplifier units SA1 and SA2 can control the potentials of the bit lines BL1 to BLm when writing data in the memory cells. The logic circuits BR1 and BR2 can perform arithmetic processing for controlling the bit lines BL1 to BLm. The data latch units LT1 and LT2 can latch write data or read data. The bit line hookup units BH1 and BH2 can drive the bit lines BL1 to BLm based on the outputs of the sense amplifier units SA1 and SA2. The row decoders RD1 to RDn can select the memory cells in the row direction. The source line drivers SD1 to SDn can drive the source line SL.

Also, upper interconnections HU1 and HU2 are provided over the memory cell array MA. Lower interconnections HDY1 and HD2Y are provided under the memory cell array MA. Lower interconnections HDX1 and HDX2 are provided under the lower interconnections HDY1 and HDY2. Also, the upper interconnections HU1 and HU2 and the lower interconnections HDX1 and HDX2 can be disposed in the row direction, and the lower interconnections HDY1 and the HDY2 can be disposed in the column direction.

The SA drivers AD1 and AD2 are respectively connected through contact plugs VA1 and VA2 to the upper interconnections HU1 and HU2. The upper interconnections HU1 and HU2 are respectively connected through contact plugs VB1 and VB2 to the lower interconnections HDY1 and HDY2. The lower interconnections HDY1 and HDY2 are respectively connected to the lower interconnections HDX1 and HDX2.

Also, the source line SL can include a first upper interconnection over the memory cell array MA. The bit lines BL1 to BLm can include a second upper interconnection on the source line SL. The upper interconnections HU1 and HU2 can include a third upper interconnection on the bit lines BL1 to BLm. Also, the lower interconnections HDY1 and HDY2 can include a first lower interconnection under the memory cell array MA. Also, the lower interconnections HDX1 and HDX2 can include a second lower interconnection under the lower interconnections HDY1 and HDY2.

The drive signals from the SA drivers AD1 and AD2 are respectively transmitted through the contact plugs VA1 and VA2 in an upward direction, and are respectively transmitted through the upper interconnections HU1 and HU2 in the row direction. Also, the signals are respectively transmitted through the contact plugs VB1 and VB2 in a downward direction, and are respectively through the lower interconnections HDY1 and HDY2 and the lower interconnections HDX1 and HDX2 to the sense amplifier circuits SP1 and SP2.

Herein, the upper interconnections HU1 and HU2 can have a lower resistance than the lower interconnections HDX1 and HDX2. For example, the upper interconnections HU1 and HU2 can have 1/20 to 1/10 times lower resistance than the lower interconnections HDX1 and HDX2. Therefore, by transmitting the drive signals from the SA drivers AD1 and AD2 through the upper interconnections HU1 and HU2 in the row direction, the propagation delay can be reduced as compared to the case of transmitting the signals through the lower interconnections HDX1 and HDX2 in the row direction.

Also, when viewed from the top side, by disposing the upper interconnections HU1 and HU2 outside the memory cell array MA, the contact plugs VB1 and VB2 can be disposed outside the memory cell array MA. Therefore, a region for passing the contact plugs VB1 and VB2 need not be provided in the memory cell array MA. Thus, an increase in the layout area can be suppressed, and the contact plugs VB1 and VB2 can be disposed densely. Accordingly, the propagation distance can be reduced by the lower interconnections HDX1 and HDX2, so that the propagation delay by the lower interconnections HDX1 and HDX2 can be reduced.

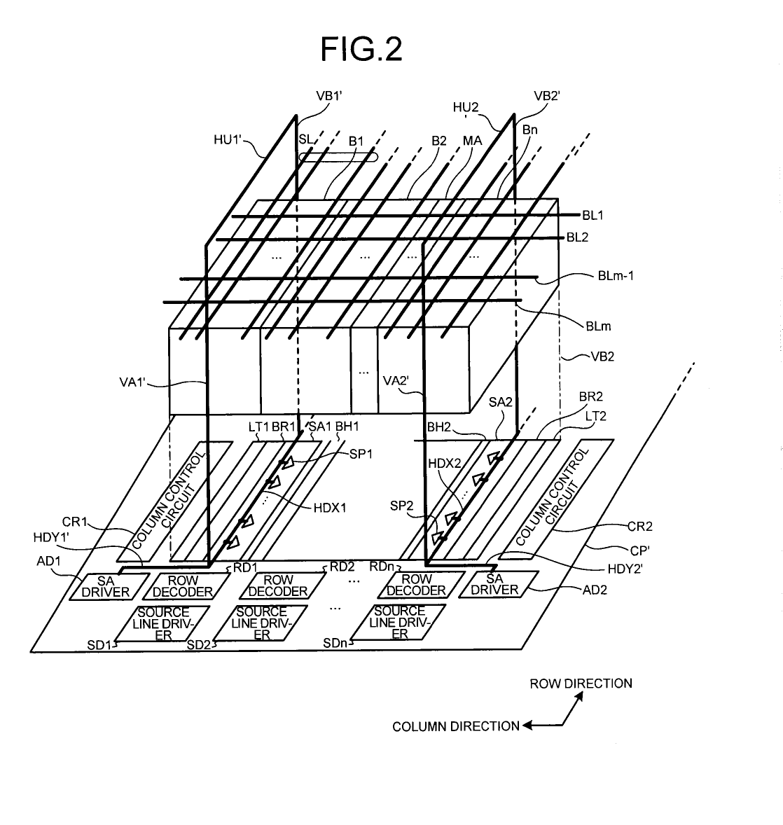

FIG. 2 is a perspective view illustrating a comparative example of the nonvolatile semiconductor memory device of FIG. 1.

Referring to FIG. 2, in a semiconductor chip CP′, upper interconnections HU1′ and HU2′, lower interconnections HDY1′ and HDY2′, and contact plugs VA1′, VA2′, VB1′ and VB2′ are provided instead of the upper interconnections HU1 and HU2, the lower interconnections HDY1 and HDY2, and the contact plugs VA1, VA2, VB1 and VB2.

Herein, the upper interconnections HU1′ and HU2′ are provided on a memory cell array MA. Also, the lower interconnections HDY1′ and HDY2′ are disposed under the memory cell array MA outside the memory cell array MA. Also, the upper interconnections HU1′ and HU2′ can be disposed in the row direction, and the lower interconnections HDY1′ and the HDY2′ can be disposed in the column direction.

The SA drivers AD1 and AD2 are respectively connected through the lower interconnections HDY1′ and HDY2′ to the lower interconnections HDX1 and HDX2. Also, the lower interconnection HDY1′ is connected through the contact plugs VA1′ and VB1′ to the upper interconnection HU1′, and the lower interconnection HDY2′ is connected through the contact plugs VA2′ and VB2′ to the upper interconnection HU2′.

The signals are respectively transmitted through the lower interconnections HDY1′ and HDY2′ in the column direction, and are respectively through the lower interconnections HDX1′ and HDX2′ to the sense amplifier circuits SP1 and SP2.

Also, the drive signals transmitted through the lower interconnections HDY1′ and HDY2′ are respectively transmitted through the contact plugs VA1′ and VA2′ in the upward direction, and are respectively transmitted through the upper interconnections HU1′ and HU2′ in the row direction. Also, the signals are respectively transmitted through the contact plugs VB1′ and VB2′ in the downward direction, and are respectively through the lower interconnections HDX1′ and HDX2′ in the row direction.

Herein, the upper interconnections HU1′ and HU2′ can have a lower resistance than the lower interconnections HDX1′ and HDX2′. For example, the upper interconnections HU1′ and HU2′ can have 1/20 to 1/10 times lower resistance than the lower interconnections HDX1′ and HDX2′. Therefore, by transmitting the drive signals from the SA drivers AD1 and AD2 through the upper interconnections HU1′ and HU2′ in the row direction, the propagation delay can be reduced as compared to the case of transmitting the signals through the lower interconnections HDX1′ and HDX2′ in the row direction.

Herein, since the word line and the bit lines BL1 to BLm are disposed densely in the memory cell array MA, it is difficult to secure a space for passing the contact plugs VA1′, VA2′, VB1′ and VB2′ through the memory cell array MA. Therefore, since the contact plugs VA1′, VA2′, VB1′ and VB2′ need be disposed outside the memory cell array MA, the connection distance between the upper interconnections HU1′ and HU2′ and the lower interconnections HDX1′ and HDX2′ is increasing.

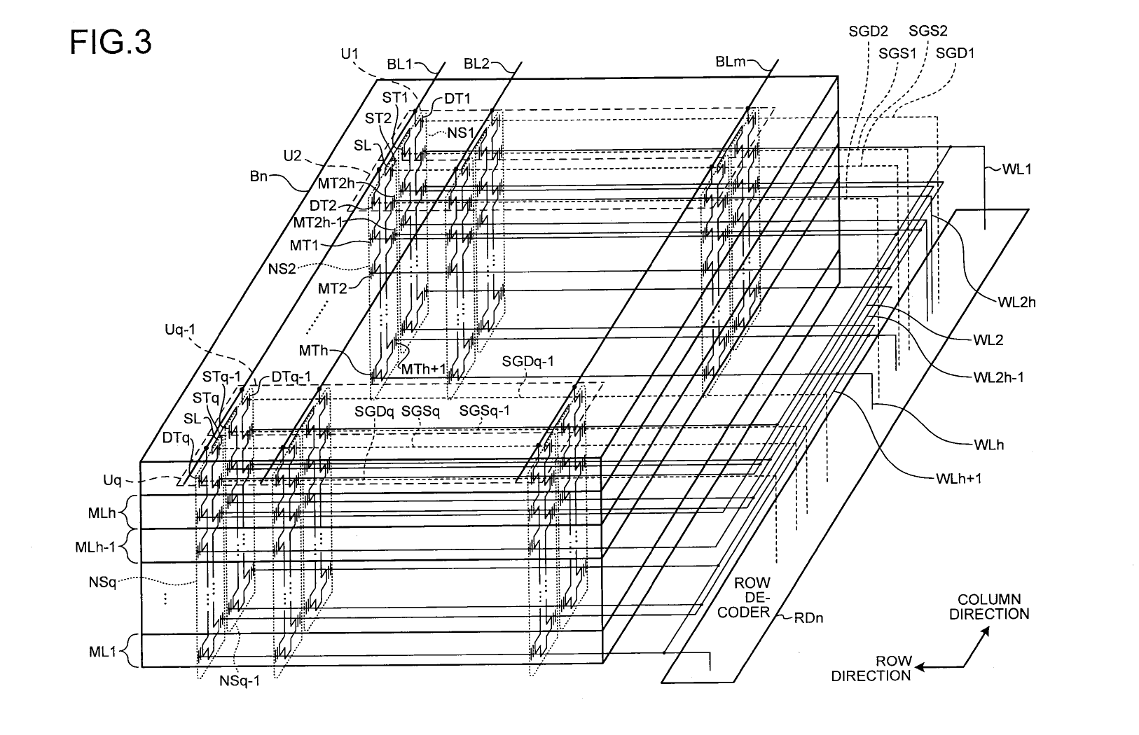

FIG. 3 is a circuit diagram illustrating a schematic block configuration of the nonvolatile semiconductor memory device of FIG. 1. Also, the example of FIG. 3 describes three-dimensional NAND flash memory including memory cells disposed three-dimensionally in the row, column and height directions. Also, the example of FIG. 3 illustrates a method in which word lines WL1 to WLh and (drain-side) select gate lines SGD1 to SGDn extend in the opposite direction to word lines WLh+1 to WL2h and (source-side) select gate lines SGS1 to SGSn.

Referring to FIG. 3, the memory cell array MA of FIG. 1 has a hierarchical structure of block→string unit→NAND string.

In the memory cell array MA, an n (n is a positive integer greater than or equal to 2) number of blocks B1 to Bn are disposed in the column direction. In each of the blocks B1 to Bn, h-layer (h is a positive integer) cell layers ML1 to MLh are stacked with an interlayer insulating film (not illustrated) interposed therebetween. Also, in each of the blocks B1 to Bn, a q (q is a positive integer) number of string units U1 to Uq are disposed in parallel in the column direction. Also, in each of the string units U1 to Uq, an m (m is a positive integer) number of NAND strings NS1 to NSq are disposed in parallel in the row direction. Each of the NAND strings NS1 to NS includes a 2h (h is a positive integer) number of cell transistors MT1 to MT2h, select transistors ST and DT disposed at both ends of the 2h cell transistors, and a back-gate transistor provided between the h cell transistors MT1 to MTh and the h cell transistors MTh+1 to MT2h.

Also, the respective cell transistors MT1 to MT2h are sequentially connected in series. The cell transistors MT1 to MT2h are disposed in ascending order from the bit line BL to the source line SCE. It is folded back between the cell transistors MTh and MTh+1 through the back-gate transistor in the column direction (a configuration of the memory cell array will be described below in detail).

Also, in each of the blocks B1 to Bn, the word lines WL1 to WL2h, the drain-side select gate lines SGD1 to SGDq, and the source-side select gate lines SGS1 to SGSq are provided in parallel in the column direction, and the bit lines BL1 to BLm are provided in parallel in the row direction.

Herein, the word lines WL1 to WL2h, the drain-side select gate lines SGD1 to SGDq, and the source-side select gate lines SGS1 to SGSq are separately provided in each of the blocks B1 to Bn. The bit lines BL1 to BLm are shared between the blocks B1 to Bn.

The blocks B1 to Bn are respectively provided with row decoders RD1 to RDn and RS1 to RSn. For example, in the block Bn, the word lines WL1 to WLh and the drain-side select gate lines SGD1 to SGDq extend in the opposite direction to the word lines WLh+1 to WL2h and the source-side select gate lines SGS1 to SGSq. The row decoder RDn is disposed in the extension direction of the word lines WL1 to WLh and the drain-side select gate lines SGD1 to SGDq. The row decoder RSn is disposed in the extension direction of the word lines WLh+1 to WL2h and the drain-side select gate lines SGS1 to SGSq.

Also, in each of the blocks B1 to Bn, the drain-side select gate lines SGD1 to SGDq and the source-side select gate lines SGS1 to SGSq are separately provided in each of the string units U1 to Uq.

In the blocks B1 to Bn, the word lines WL1 to WLh are connected in common to the gates of the corresponding cell transistors MT1 to MTh among different string units U1 to Uq. That is, for example, in the block B1, the word line WL1 is connected in common to the gate of the cell transistor MT1 of the string units U1 to Uq. For example, in the block B1, the word line WL2 is connected in common to the gate of the cell transistor MT2 of the string units U1 to Uq. Like the word lines WL1 and WL2, the word lines WL3 to WLh are connected in common to the gates of the corresponding cell transistors MT3 to MTh.

In the blocks B1 to Bn, the word lines WLh+1 to WL2h are connected in common to the gates of the corresponding cell transistors MTh+1 to MT2h among different string units U1 to Uq.

In the blocks B1 to Bn, unlike the case (comparative example) of extending the word line WL in each of the string units U1 to Uq, in the present embodiment, the word lines are connected in common to the gates of the corresponding cell transistors MT1 to MTh of different string units U1 to Uq. Accordingly, in the present embodiment, the extension lines from the word lines WL1 to WL2h can be reduced by 1/q as compared to the comparative example. As a result, the present embodiment can suppress the large dimension of row decoders 71 and 72 as compared to the comparative example.

Also, by dividing the word lines WL1 to WL2h in the respective blocks B1 to Bn, even when the word lines WL1 to WL2h are shared between a plurality of different string units in the same blocks B1 to Bn, an increase in the load applied to drive the word lines WL1 to WL2h can be suppressed.

Also, the string units U1 to Uq are provided with select transistors DT1 to DTq and ST1 to STq selecting the string units U1 to Uq. The cell transistors MT1 of the NAND strings NS1 to NSq are respectively connected through the select transistors DT1 to DTq to the bit lines BL1 to BLm. Also, the cell transistors MT2h of the NAND strings NS1 to NSq are respectively connected through the select transistors DT1 to DTq to the source line SCE.

Also, the drain-side select gate lines SGD1 to SGDq are respectively connected to the gates of the select transistors DT1 to DTq, and the source-side select gate lines SGS1 to SGSq are respectively connected to the gates of the select transistors ST1 to STq.

Also, among the cell transistors sharing the word line WL, a plurality of cell transistors located in the common string units U1 to Uq constitute a page. The page is the unit of writing data in the memory cells, and is the unit of reading data from the memory cells.

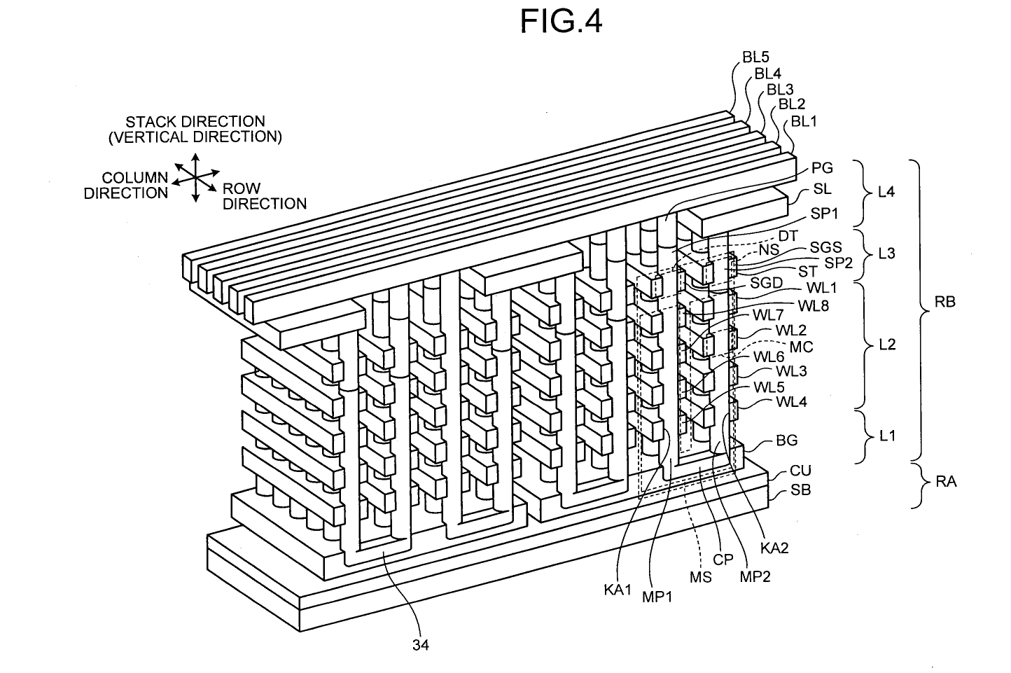

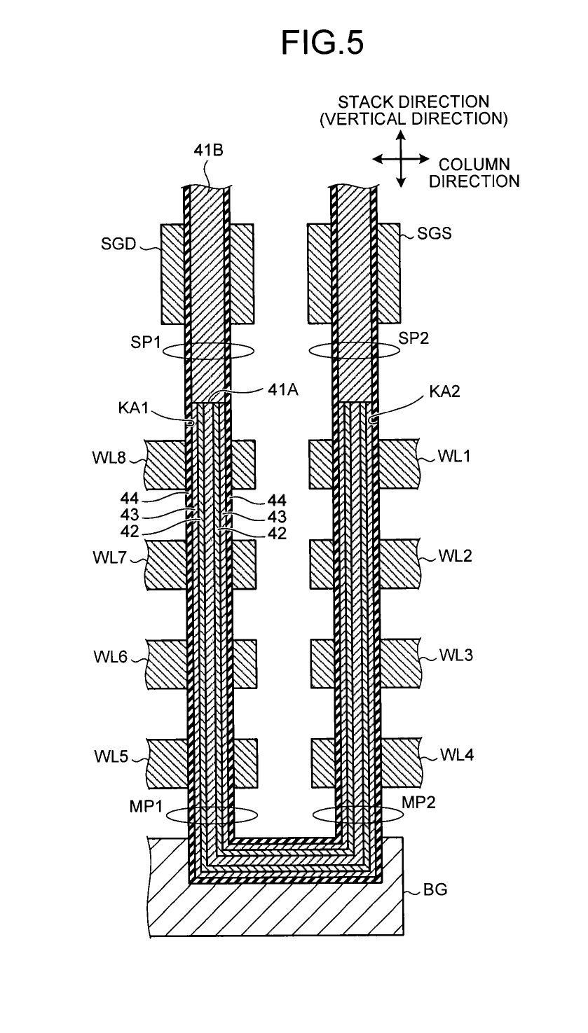

FIG. 4 is a perspective view illustrating a schematic configuration of the memory cell array of the nonvolatile semiconductor memory device of FIG. 1, and FIG. 5 is an enlarged cross-sectional view of the NAND string NS of FIG. 4.

As illustrated, the memory cell array includes a circuit region RA and a memory region RB. The circuit region RA is formed in the semiconductor substrate. The memory region RB is formed in the circuit region RA.

The memory cell array includes a circuit layer CU, a back-gate transistor layer L1, a memory cell transistor layer L2, a select transistor layer L3, and an interconnection layer L4 that are sequentially formed on the semiconductor substrate SB.

The back-gate transistor layer L1 functions as a back-gate transistor. The memory cell transistor layer L2 functions as memory cell transistors MT1 to MT8. The select transistor layer L3 functions as select transistors ST and DT. The interconnection layer L4 functions as a source line SL and bit lines BL1 to BL5.

The back-gate transistor layer L1 includes a back-gate layer BG. The back-gate layer BG is formed to be two-dimensionally widened in the row direction and the column direction parallel to the semiconductor substrate SB. The back-gate layer BG is divided in the respective blocks B1 to Bn. The back-gate layer BG is formed of, for example, a polysilicon.

Also, the back-gate layer BG includes a back-gate hole. The back-gate hole is formed to engrave the back-gate layer BG. When viewed from the top side, the back-gate hole is formed in a substantially rectangular shape having the column direction as a length direction.

The memory cell transistor layer L2 is formed on the back-gate transistor layer L1. The memory cell transistor layer L2 includes word lines WL1 to WL8. The word lines WL1 to WL8 are stacked with an interlayer insulating layer (not illustrated) interposed therebetween. The word lines WL1 to WL8 is formed in a stripe shape that has a predetermined pitch in the column direction and extends in the row direction. The word lines WL1 to WL8 are formed of, for example, polysilicon.

Also, the memory cell transistor layer L2 includes memory holes KA1 and KA2. The memory holes KA1 and KA2 are formed to penetrate the word lines WL1 to WL8. The memory holes KA1 and KA2 are formed to match the edge neighborhood of the back-gate hole in the column direction.

Also, as illustrated in FIG. 5, the back-gate transistor layer L1 and the memory cell transistor layer L2 include a block insulating layer 44, a charge storage layer 43, a tunnel insulating layer 42, and a semiconductor layer 41A. The semiconductor layer 41A functions as a body of the NAND string (back gate of each transistor).

As illustrated in FIG. 5, the block insulating layer 44 is formed with a predetermined thickness on the sidewalls facing the back-gate hole and the memory holes KA1 and KA2. The charge storage layer 43 is formed with a predetermined thickness on the side surface of the block insulating layer 44. The tunnel insulating layer 42 is formed with a predetermined thickness on the side surface of the charge storage layer 43. The semiconductor layer 41A is formed to contact the side surface of the tunnel insulating layer 42. The semiconductor layer 41A is formed to fill the back-gate hole and the memory holes KA1 and KA2.

The semiconductor layer 41A is formed in a U shape when viewed in the column direction. That is, the semiconductor layer 41A includes a pair or pillar portions MP1 and MP2 extending in the vertical direction with respect to the surface of the semiconductor substrate SB, and a connection portion connecting the bottoms of the pair of pillar portions MP1 and MP2.

The block insulating layer 44 is formed of, for example, a silicon dioxide (SiO₂). The charge storage layer 43 is formed of, for example, a silicon nitride (SiN). The semiconductor layer 41A is formed of a polysilicon. The block insulating layer 44, the charge storage layer 43, the tunnel insulating layer 42, and the semiconductor layer 41A form a MONOS-type transistor functioning as a memory transistor MT.

In other words, as for the configuration of the back-gate transistor layer L1, the tunnel insulating layer 42 is formed to surround the connection portion. A back-gate conductive layer 40 is formed to surround the connection portion.

Also, as for the configuration of the memory transistor layer L2, the tunnel insulating layer 42 is formed to surround the pillar portions MP1 and MP2. The charge storage layer 43 is formed to surround the tunnel insulating layer 42. The block insulating layer 44 is formed to surround the charge storage layer 43. The word lines WL1 to WL8 are formed to surround the block insulating layer 44.

As illustrated in FIG. 4, the select transistor layer L3 includes select gate lines SGS and SGD. The select gate lines SGS and SGD are formed in a stripe shape that has a predetermined pitch in the column direction and extends in the row direction. A pair of select gate lines SGS and a pair of select gate lines SGD are disposed alternately in the column direction. The select gate line SGS is formed on the one-side pillar portion MP2, and the select gate line SGD is formed on the other-side pillar portion MP1. The select gate lines SGS and SGD are formed of a polysilicon.

As illustrated in FIG. 4, the select transistor layer L3 includes pillar portions SP1 and SP2. The pillar portions SP1 and SP2 respectively penetrate the select gate lines SGS and SGD. The pillar portions SP1 and SP2 are respectively formed to match the pillar portions MP1 and MP2.

The select transistor layer L3 includes a block insulating layer 44 and a semiconductor layer 41B. The block insulating layer 44 is formed on the sidewalls facing the memory holes KA1 and KA2. The semiconductor layer 41B is formed in a pillar shape extending in the vertical direction with respect to the surface of the semiconductor substrate SB, in such a way as to contact the block insulating layer 44.

The block insulating layer 44 is formed of, for example, a silicon dioxide (SiO₂). The semiconductor layer 41B is formed of, for example, a polysilicon.

As illustrated in FIG. 4, the interconnection layer L4 is formed on the select transistor layer L3. The interconnection layer L4 includes a source line SL, a plug PG, and bit lines BL1 to BL5.

The source line SL is formed in a plate shape extending in the row direction. The source line SL is formed to contact the top surface of a pair of select gate lines SGS adjacent in the column direction. The plug PG is formed to contact the top surface of the select gate line SGD and extend in the vertical direction with respect to the surface of the semiconductor substrate SB. The bit lines BL1 to BL5 are formed in a stripe shape that has a predetermined pitch in the row direction and extends in the column direction. The bit lines BL1 to BL5 are formed to contact the top surface of the plug PG. The source line SL, the plug PG, and the bit lines BL1 to BL5 are formed of, for example, a metal such as tungsten (W).

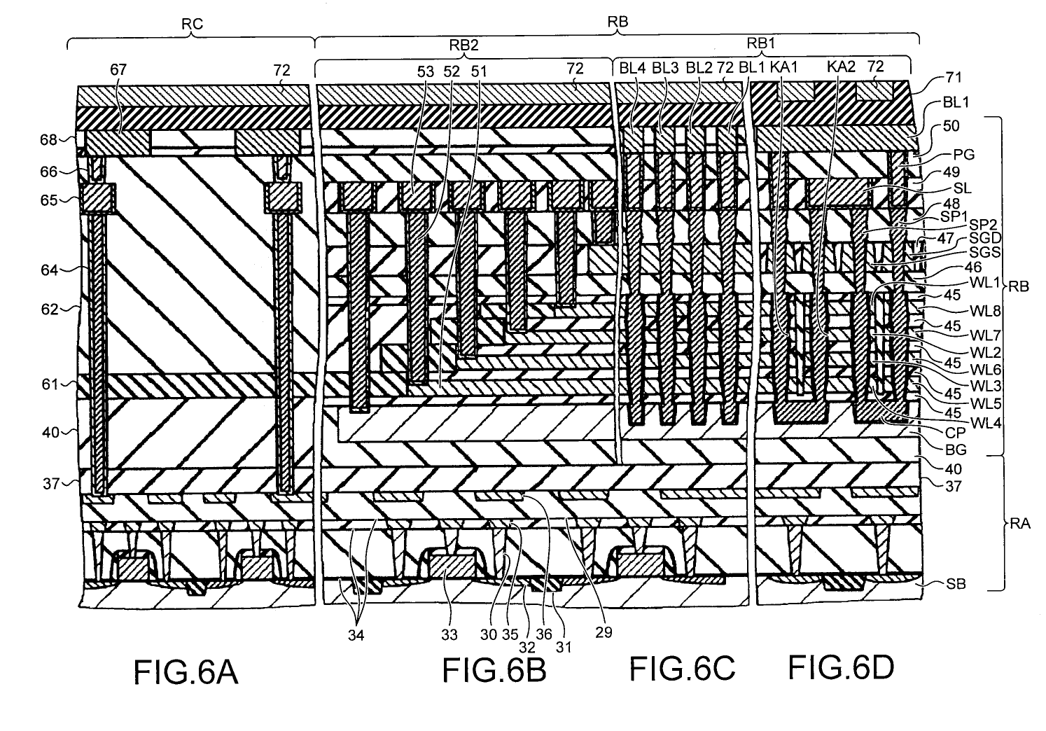

FIG. 6A is a cross-sectional view illustrating a schematic configuration of the peripheral circuit region of the nonvolatile semiconductor memory device of FIG. 1, FIG. 6B is a cross-sectional view illustrating a schematic configuration of the word line extension portion of the nonvolatile semiconductor memory device of FIG. 1, FIG. 6C is a cross-sectional view illustrating a schematic configuration of the memory cell array of FIG. 1 cut in a word line direction, and FIG. 6D is a cross-sectional view illustrating a schematic configuration of the memory cell array of FIG. 1 cut in a bit line direction.

Referring to FIGS. 6A to 6D, a peripheral region RC is provided around a memory region RB. Also, the peripheral region RC may be provided with a circuit region RA. Also, the memory region RB is provided with a memory cell region RB1 and an extension region RB2.

In the circuit region RA, the semiconductor substrate SB is device-isolated by a STI (Shallow Trench Isolation) 31. A diffusion layer 32 is formed in an active region device-isolated by the STI 31, and a gate electrode 33 is disposed on a channel region between the diffusion layers 32, thereby forming a transistor. Also, an interlayer insulating film 34 is formed on the semiconductor substrate SB including the transistor, and a plug 30 and an interconnection 35 are buried in the interlayer insulating film 34. Also, an interlayer insulating film 29 is formed on the interconnection 35, and an interconnection 36 is formed on the interlayer insulating film 29. Interlayer insulating films 37 and 40 are formed on the interconnection 36. Also, the interconnection 35 can be used as the lower interconnections HDX1 and HDX2 of FIG. 1. The interconnection 36 can be used as the lower interconnections HDY1 and HDY2 of FIG. 1.

Also, in the memory cell region RB1, a back-gate layer BG is formed on the interlayer insulating film 40, and a connection layer CP is formed on the back-gate layer BG. The word lines WL1 to WL4 are stacked with an interlayer insulating film 45 interposed therebetween, and the word lines WL5 to WL8 are stacked with the interlayer insulating film 45 interposed therebetween.

Also, a select gate line SGS is formed on the word line WL1 with an interlayer insulation film 46 interposed therebetween, and a select gate line SGD is formed on the word line WL8 with the interlayer insulation film 46 interposed therebetween. Also, an interlayer insulating film 47 is buried between the select gate lines SGS and SGD.

Also, a source line SL is formed on the select gate line SGS with an interlayer insulting film 48 interposed therebetween, and the source line SL is buried with an interlayer insulating film 49. Also, the bit line BL1 is formed on the select gate line SGD and the source line SL with an interlayer insulting film 50 interposed therebetween.

Also, in the extension region RB2, the back-gate layer BG is formed on the interlayer insulating film 40. An extension line 51 extending from the word lines WL1 to WL8 are formed in each layer. Herein, the end of the extension line 51 is disposed in a stepwise configuration shifted in each layer, so that the end of the extension line 51 of each layer does not overlap in the vertical direction. The end of the extension line 51 of each layer is connected through a plug 52 to an interconnection 53, so that the word lines WL1 to WL8 are connected to a circuit layer CU.

Also, in the peripheral region RC, interlayer insulating films 61, 62 and 68 are formed on the interlayer insulating film 40. Plugs 64 and 66 and interconnections 65 and 67 are buried in the interlayer insulating films 37, 42, 61, 62 and 68. An interlayer insulating film 71 is formed on the bit line BL1 and the interconnection 67. An interconnection 72 is buried in the interlayer insulating film 71. Also, the interconnection 72 can be used as the upper interconnections HU1 and HU2 of FIG. 1.

### Second Embodiment

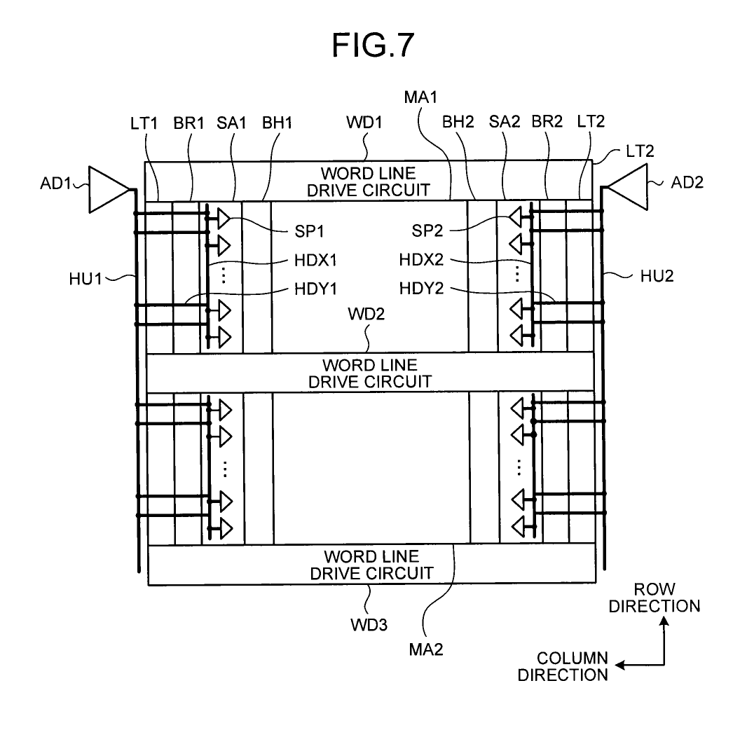

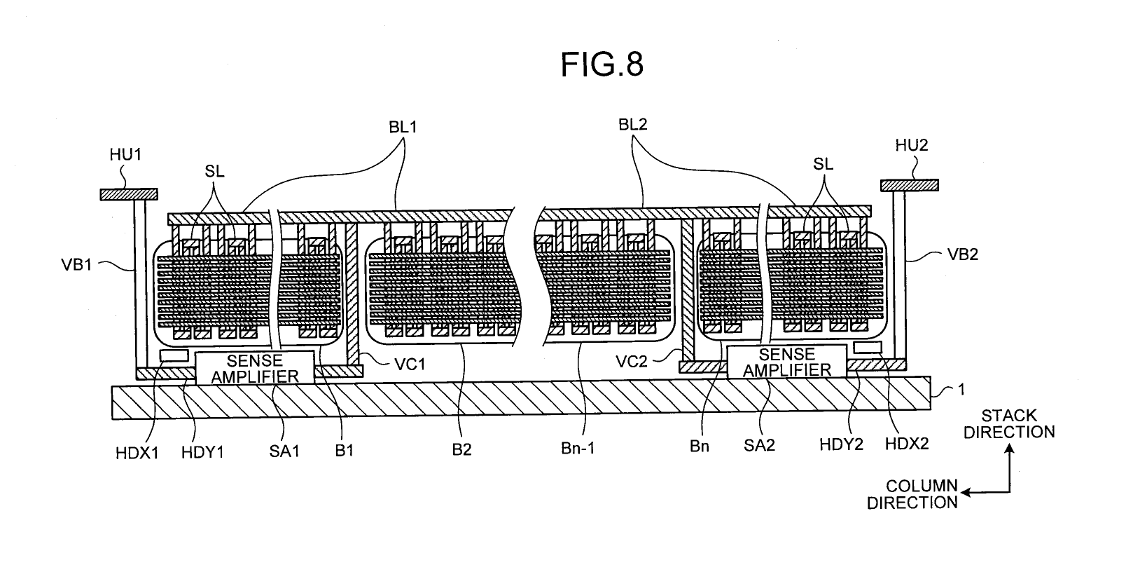

FIG. 7 is a plan view illustrating a schematic configuration of a nonvolatile semiconductor memory device according to a second embodiment, and FIG. 8 is a cross-sectional view illustrating a schematic configuration of the memory cell array of FIG. 7 cut in a bit line direction.

Referring to FIG. 7, in the nonvolatile semiconductor memory device, the memory cell array MA of FIG. 1 is divided into memory cell arrays MA1 and MA2. Also, as illustrated in FIG. 7, a contact plug VC1 is provided between the blocks B1 and B2, and a contact plug VC2 is provided between the blocks Bn−1 and Bn. The bit line BL1 is connected through the contact plug VC1 to the sense amplifier unit SA1, and the bit line BL2 is connected through the contact plug VC2 to the sense amplifier unit SA2.

Herein, word line drive circuits WD1 to WD3 are provided between the end of the memory cell arrays MA1 and MA2 and the memory cell arrays MA1 and MA2. The word line drive circuits WD1 to WD3 can assist in driving the word lines WL1 to WL2h by the row decoders RD1 to RDn. Also, upper interconnections HU1 and HU2 are disposed outside the memory cell arrays MA1 and MA2 to be shared between the memory cell arrays MA1 and MA2.

Herein, by providing the word line drive circuits WD1 to WD3, the load on the row decoders RD1 to RDn can be reduced. Also, by disposing the upper interconnections HU1 and HU2 outside the memory cell arrays MA1 and MA2, the contact plugs VB1 and VB2 can be disposed densely, so that the propagation delay by the lower interconnections HDX1 and HDX2 can be reduced.

### Third Embodiment

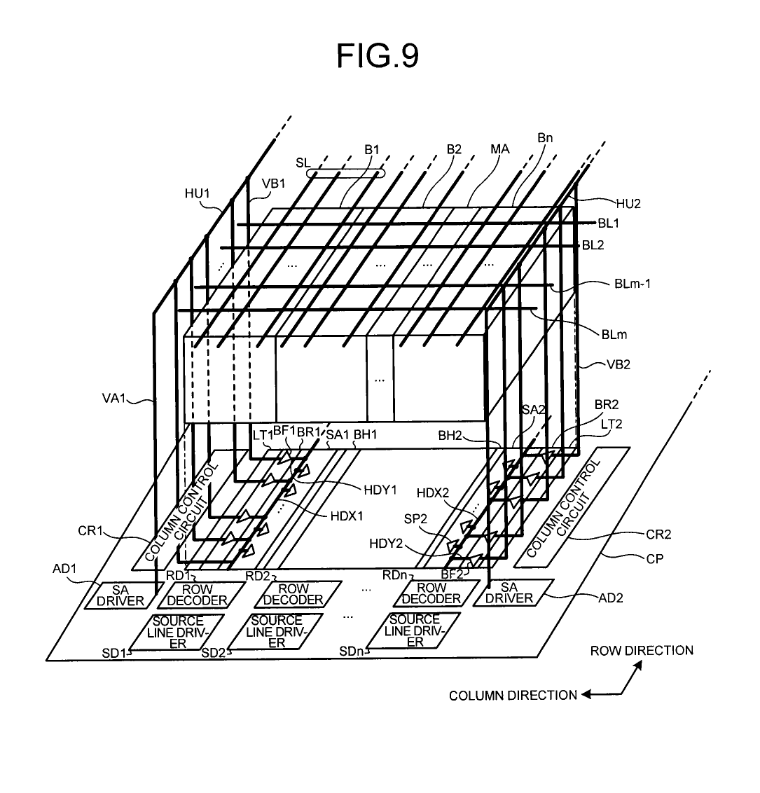

FIG. 9 is a perspective view illustrating a schematic configuration of a nonvolatile semiconductor memory device according to a third embodiment. Referring to FIG. 9, in the nonvolatile semiconductor memory device, buffers BF1 and BF2 are added to the memory cell array MA of FIG. 1. Herein, the buffers BF1 and BF2 can amplify the drive signals that are respectively transmitted through the lower interconnections HDY1 and HDY2. Also, the buffer BF1 and BF2 may be disposed between the sense amplifier units SA1 and SA2 and the logic circuits BR1 and BR2, may be disposed between the logic circuits BR1 and BR2 and the data latch units LT1 and LT2, may be disposed in an empty region of the logic circuits BR1 and BR2, and may be disposed in an empty region of the data latch units LT1 and LT2.

Herein, by providing the buffers BF1 and BF2, the drive signals transmitted respectively through the lower interconnections HDY1 and HDY2 can be amplified, so that the propagation delay can be reduced. Also, by disposing the buffers BF1 and BF2 under the memory cell array MA, an increase in the layout area can be prevented and the load on the SA drivers AD1 and AD2 can be reduced, so that the size of the SA drivers AD1 and AD2 can be reduced.

### Fourth Embodiment

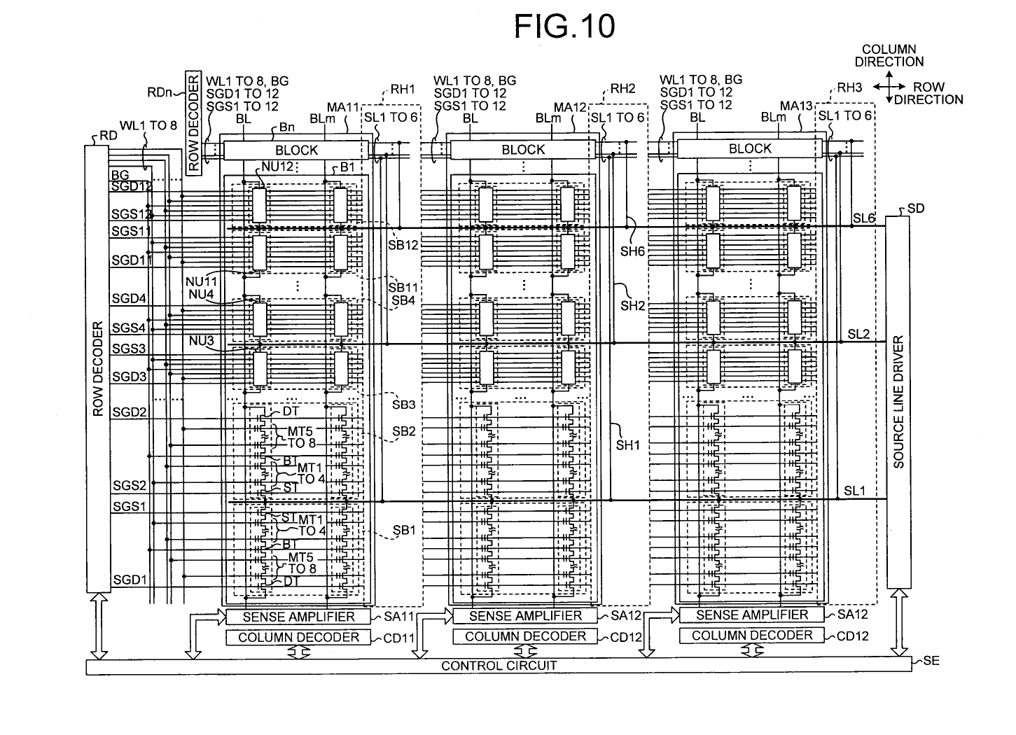

FIG. 10 is a block diagram illustrating a schematic configuration of a nonvolatile semiconductor memory device according to a fourth embodiment.

Referring to FIG. 10, in the nonvolatile semiconductor memory device, the memory cell array MA of FIG. 1 is divided into memory cell arrays MA11 to MA13. Herein, the memory cell arrays MA11 to MA13 are provided with blocks B1 to Bn. The blocks B1 to Bn are provided with subblocks SB1 to S12. The subblocks SB1 to SB12 are provided with NAND strings NU1 to NU12. The NAND strings NU1 to NU12 are provided with cell transistors MT1 to MT8, select transistors DT and ST, and a back-gate transistor BT.

Sense amplifiers SA11 to SA13 are provided directly under the memory cell arrays MA11 to MA13. Also, in the peripheral portions of the memory cell arrays MA11 to MA13, column decoders CD11 to CD13 are provided in the memory cell arrays MA11 to MA13, and a row decoders RD, a source line driver SD, and a control circuit SE are provided in common to the memory cell arrays MA11 to MA13. Also, the control circuit SE can control the sense amplifiers SA11 to SA13, the column decoder CD11 to CD13, the row decoder RD, and the source line driver SD.

Herein, in the memory cell arrays MA11 to MA13, a plurality of source lines SL1 to SL6 are provided in a divided manner. The source line driver SD can separately drive the source lines SL1 to SL6 to supply a source potential to the NAND strings NU1 to NU12. For example, the source line SL1 can supply a source potential to the NAND strings NU1 and NU2, the source line SL2 can supply a source potential to the NAND strings NU3 and NU4, and the source line SL6 can supply a source potential to the NAND strings NU11 and NU12.

Herein, shunt regions RH1 to RH3 shunting the source lines SL1 o SL6 between the blocks B1 to Bn are provided between the memory cell arrays MA11 to MA13. Herein, in the shunt regions RH1 to RH3, shunt lines SH1 to SH6 are provided in the respective source lines SL1 to SL6. For example, the source line SL1 is shunted between the blocks B1 to Bn through the shunt line SH1. The source line SL2 is shunted between the blocks B1 to Bn through the shunt line SH2. The source line SL6 is shunted between the blocks B1 to Bn through the shunt line SH6.

Herein, by providing a plurality of source lines SL1 to SL6 in a divided manner, the load on the source line driver SD can be reduced and the source lines SL1 to SL6 can be shunted between the blocks B1 to Bn. Accordingly, the low resistance of the source lines SL1 to SL6 can be implemented, and the source potential can be uniform.

Also, by providing the lower interconnections HDY1 and HDY2 of FIG. 1 in the empty region of the shunt regions RH1 to RH3, the region for the lower interconnections HDY1 and HDY2 need not be secured. Accordingly, an increase in the layout area can be prevented.

Also, in the above-described embodiments, the method of transmitting the drive signals from the SA drivers AD1 and AD2 through the upper interconnections HU1 and HU2 has been described as an example. However, the signals transmitted through the upper interconnections HU1 and HU2 are not limited to the drive signals, but may be any other signals that are transmitted to the column system circuit. For example, the signals transmitted through the upper interconnections HU1 and HU2 may be signals supplied to the logic circuits BR1 and BR2, may be signals supplied to the data latch units LT1 and LT2, and may be signals supplied to the bit line hookup units BH1 and BH2. Also, the global signal is a signal that is provided in common to a plurality of columns of the column system circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Structure of the memory cell array 10 is not limited as above description. A memory cell array formation may be disclosed in U.S. patent application Ser. No. 12/532,030 filed on Mar. 23, 2009. U.S. patent application Ser. No. 12/532,030, the entire contents of which are incorporated by reference herein.

Furthermore A memory cell array formation may be disclosed in U.S. patent application Ser. No. 12/679,991 filed on Mar. 25, 2010. U.S. patent application Ser. No. 13/236,734, the entire contents of which are incorporated by reference herein. We may modify the memory cell array of FIG. 1 and FIG. 9 in No. 13/236,734 so that the memory cell array is formed above the semiconductor substrate 1.

In particular, a conductive layer is formed above the semiconductor substrate 1. The memory cell array is formed on the conductive layer. A peripheral circuit including a sense amplifier circuit is formed below the memory cell array and formed on the semiconductor substrate 1. We may apply the first embodiment to the fourth embodiment to memory device including the modified memory cell array.

What is claimed is:

1. A nonvolatile semiconductor memory device comprising:
a memory cell array including NAND strings with memory cells stacked;
a bit line connected to the NAND string;
word lines connected to gates of the memory cells;
a column system circuit disposed under the memory cell array;
a global signal supply unit configured to supply a global signal to the column system circuit;
an upper interconnection disposed over the bit line outside the memory cell array, when viewed from the top side, the upper interconnection being connected to the global signal supply unit;
a lower interconnection disposed under the memory cell array, the lower interconnection being connected to the column system circuit; and
a contact plug connected to both the upper interconnection and the lower interconnection.

2. The nonvolatile semiconductor memory device according to claim 1, wherein the contact plug is disposed outside the memory cell array when viewed from the top side.

3. The nonvolatile semiconductor memory device according to claim 1, wherein the bit line extends in a column direction and the upper interconnection extends in a row direction.

4. The nonvolatile semiconductor memory device according to claim 1, wherein the column system circuit includes a sense amplifier circuit configured to detect a potential of the bit line or cell current.

5. The nonvolatile semiconductor memory device according to claim 4, wherein the global signal supply unit is a SA driver configured to drive the sense amplifier circuit.

6. The nonvolatile semiconductor memory device according to claim 1, further comprising a buffer disposed under the memory cell array to amplify the global signal.

7. The nonvolatile semiconductor memory device according to claim 1, wherein the memory cell array is divided into more than one, and a word line drive circuit is provided between the divided memory cell arrays.

8. The nonvolatile semiconductor memory device according to claim 1, wherein the contact plug is disposed outside the memory cell in a column direction.

9. The nonvolatile semiconductor memory device according to claim 1, wherein the contact plug is disposed outside the memory cell in a row direction.

10. The nonvolatile semiconductor memory device according to claim 1, comprising:
a row decoder disposed outside the memory cell array when viewed from the top side; and
a column control circuit including a column decoder disposed outside the memory cell array when viewed from the top side.

11. A nonvolatile semiconductor memory device comprising:
a memory cell array including NAND strings with memory cells stacked;
a source line disposed over the memory cell array and connected to one end of the NAND string;
a bit line disposed over the source line and connected to the other end of the NAND string;
word lines connected to gates of the memory cells;
a column system circuit disposed under the memory cell array;
a global signal supply unit configured to supply a global signal to the column system circuit;
a shunt region disposed perpendicular to the source line to shunt the source line between blocks of the memory cell array;
an upper interconnection disposed over the bit line outside the memory cell array, when viewed from the top side, the upper interconnection being connected to the global signal supply unit;
a lower interconnection disposed under the memory cell array, the lower interconnection being connected to the column system circuit; and
a contact plug connected to both the upper interconnection and the lower interconnection.

12. The nonvolatile semiconductor memory device according to claim 11, wherein the lower interconnection is disposed in the shunt region.

13. The nonvolatile semiconductor memory device according to claim 11, wherein the bit line extends in a column direction and the upper interconnection extends in a row direction.

14. The nonvolatile semiconductor memory device according to claim 11, wherein the column system circuit includes a sense amplifier circuit configured to detect a potential of the bit line or cell current.

15. The nonvolatile semiconductor memory device according to claim 14, wherein the global signal supply unit is a SA driver configured to drive the sense amplifier circuit.

16. The nonvolatile semiconductor memory device according to claim 11, further comprising a buffer disposed directly under the memory cell array to amplify the global signal transmitted through the lower interconnection.

17. The nonvolatile semiconductor memory device according to claim 11, wherein the memory cell array is divided into more than one, and a word line drive circuit is provided between the divided memory cell arrays.

18. The nonvolatile semiconductor memory device according to claim 11, wherein in the memory cell array, the NAND string is arranged in plurality in a row direction to constitute a string unit, and the string unit is arranged in plurality in a column direction to constitute a block.

19. The nonvolatile semiconductor memory device according to claim 18, comprising a select gate line disposed over the word line and under the bit line and provided at each of the string units.

20. The nonvolatile semiconductor memory device according to claim 11, comprising:
a row decoder disposed outside the memory cell array when viewed from the top side;
a column control circuit including a column decoder disposed outside the memory cell array when viewed from the top side; and
a source line driver configured to drive the plurality of source lines in a divided manner.
